(19) United States
(12) Patent Application Publication
(10) Pub. No.: US 2018/0108297 A1
(43) Pub. Date: Apr. 19, 2018

(54) AMOLED DISPLAY PANEL DETECTION METHOD AND DETECTION DEVICE

(71) Applicant: Shenzhen China Star Optoelectronics Technology Co., Ltd., Shenzhen (CN)

(72) Inventors: Zhenling Wang, Shenzhen City (CN); Taijiun Hwang, Shenzhen City (CN)

(21) Appl. No.: 15/114,849

(22) PCT Filed: Jun. 20, 2016
(86) PCT No.: PCT/CN2016/086432

§ 371 Date: Jul. 28, 2016

(30) Foreign Application Priority Data
Mar. 25, 2016 (CN) 201610178387.9

(51) Int. Cl. G09G 3/3258; H01L 27/32; H01L 51/00; H01L 51/56

(52) U.S. Cl. CPC G09G 3/3258; H01L 27/3244; H01L 51/0031; H01L 2251/568; G09G 2330/021; H01L 2251/562; H01L 51/56

(57) ABSTRACT

Disclosed are an AMOLED display panel detection method and a detection device. The temperature detection module (3) is set to shoot and record the temperatures of the respective display regions of the AMOLED display panel (2). As the temperature detection module (3) detects that the temperature of some display region exceeds the threshold voltage, it indicates that the AMOLED display panel (2) has the short circuit and the micro short circuit existing conditions. Thus, the AMOLED display panel (2) can be effectively detected and intercepted in time to prevent the same flowing to the rear end assembly process; moreover, the resistance detection module (4) is set to perform the resistance detection to the display region exceeding the threshold temperature to find out the positions appearing the short circuit and the micro short circuit in the AMOLED display panel (2) for performing the accurate repair and raising the panel yield.

### FIELD OF THE INVENTION

The present invention relates to a manufacture field of an Organic Light Emitting Diode, and more particularly to an AMOLED display panel detection method and a detection device.

### BACKGROUND OF THE INVENTION

The Organic Light Emitting Display (OLED) panel possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display panel.

The OLED panel can be categorized into two major types according to the driving methods, which are the Passive Matrix OLED (PMOLED) and the Active Matrix OLED (AMOLED). The AMOLED display panel comprises pixels aligned in array. Each pixel is driven by the drive circuit consisted of a plurality of thin film transistors and capacitors, which belongs the active display type. The illumination efficiency is high, and generally utilized for the high resolution large scale display device.

The AMOLED is a current driving element. When the electrical current flows through the organic light emitting diode, the organic light emitting diode emits light, and the brightness is determined according to the current flowing through the organic light emitting diode itself. Before the AMOLED display panel leaves the factory, it is required to perform detection to the AMOLED display panel.

As shown in FIG. 1, the AMOLED display panel detection device according to prior art merely comprises a detection signal generation module 100 and an AMOLED display panel 200 electrically coupled to the detection signal generation module 100 in general. The detection signal generation module 100 provides a power source positive voltage OVDD, a power source negative voltage OVSS, a detection data signal Data and a detection scan signal Gate to the AMOLED display panel 200. The AMOLED display panel 200 receives respective signal to show a test image. The technician determines whether the dot and line defects exist in the AMOLED display panel 200 with eyes or with the image capture apparatus. Such kind of detection is applied for the condition that the short circuit or open circuit happens in the AMOLED display panel 200, and cannot detect the condition of the micro short circuit appearing in the AMOLED display panel 200.

The micro short circuit means that in the manufacture process of the AMOLED display panel, the tiny particles will cause the over small line resistance appearing between the data line and the scan line (or the power source positive line and the power source negative line) in the panel, but no phenomenon causing the dot or line defects. The micro short circuit will cause that the current driving the organic light emitting diode is larger than the expected current value corresponding to the data signal. Then, the brightness and the temperature of the organic light emitting diode raise. The raise of the panel temperature will further cause the current increase, temperature raise to lead to form the vicious cycle. Ultimately, it results in aging and burning down of the AMOLED display panel. Therefore, it is truly necessary to detect the AMOLED display panel having the micro short circuit condition to be intercepted for flowing to the rear end assembly manufacture process.

### SUMMARY OF THE INVENTION

An objective of the present invention is to provide an AMOLED display panel detection method, which can effectively detect and intercept the AMOLED display panel having short circuit and micro short circuit existing conditions in time to prevent the same to flow to the rear end assembly process and to raise the panel yield.

Another objective of the present invention is to provide an AMOLED display panel detection device, which can effectively detect and intercept the AMOLED display panel having short circuit and micro short circuit existing conditions in time to prevent the same to flow to the rear end assembly process and to raise the panel yield.

For realizing the aforesaid objectives, the present invention first provides an AMOLED display panel detection method, comprising steps of:

step 1, providing an AMOLED display panel detection device; the AMOLED display panel detection device at least comprising a detection signal generation module, an AMOLED display panel electrically coupled to the detection signal generation module and a temperature detection module electrically to the AMOLED display panel;

step 2, outputting a power source positive voltage, a power source negative voltage, a detection data signal and a detection scan signal to the AMOLED display panel with the detection signal generation module to control the AMOLED display panel showing a test image;

step 3, detecting whether a bright spot and a bright line defect exist in the AMOLED display panel;

step 4, controlling the AMOLED display panel continuing to show a pure white image with the detection signal generation module, and meanwhile, shooting and recording temperatures of respective display regions of the AMOLED display panel with the temperature detection module;

step 5, setting a threshold temperature, and intercepting the AMOLED display panel, in which a temperature of any display region exceeds the threshold voltage.

The temperature detection module is a thermal imager.

In the step 4, a duration that the AMOLED display panel continues to show the pure white image is 10 minutes.

In the step 1, the AMOLED display panel detection device further comprises a resistance detection module which is electrically coupled to the AMOLED display panel.

The AMOLED display panel detection method further comprises step 6, performing resistance detection to the display region exceeding the threshold temperature in the AMOLED display panel which is intercepted with the resistance detection module to find out positions of short circuit and micro short circuit appeared in the AMOLED display panel which is intercepted.

The AMOLED display panel detection method further comprises step 7, repairing the positions of the short circuit and the micro short circuit appeared in the AMOLED display panel which is intercepted with laser.

The present invention further provides an AMOLED display panel detection device, at least comprising a detection signal generation module, an AMOLED display panel electrically coupled to the detection signal generation module and a temperature detection module electrically to the AMOLED display panel.

The temperature detection module is a thermal imager.

The AMOLED display panel detection device further comprises a resistance detection module which is electrically coupled to the AMOLED display panel.

The present invention further provides an AMOLED display panel detection method, comprising steps of:

step 1, providing an AMOLED display panel detection device;

the AMOLED display panel detection device at least comprising a detection signal generation module, an AMOLED display panel electrically coupled to the detection signal generation module and a temperature detection module electrically to the AMOLED display panel;

step 2, outputting a power source positive voltage, a power source negative voltage, a detection data signal and a detection scan signal to the AMOLED display panel with the detection signal generation module to control the AMOLED display panel showing a test image;

step 3, detecting whether a bright spot and a bright line defect exist in the AMOLED display panel;

step 4, controlling the AMOLED display panel continuing to show a pure white image with the detection signal generation module, and meanwhile, shooting and recording temperatures of respective display regions of the AMOLED display panel with the temperature detection module;

step 5, setting a threshold temperature, and intercepting the AMOLED display panel, in which a temperature of any display region exceeds the threshold voltage;

wherein the temperature detection module is a thermal imager;

wherein in the step 4, a duration that the AMOLED display panel continues to show the pure white image is 10 minutes.

The benefits of the present invention are: the present invention provides an AMOLED display panel detection method and a detection device. The temperature detection module is set to shoot and record the temperatures of the respective display regions of the AMOLED display panel. As the temperature detection module detects that the temperature of some display region exceeds the threshold voltage, it indicates that the AMOLED display panel has the short circuit and the micro short circuit existing conditions. Thus, the AMOLED display panel having the short circuit and the micro short circuit existing conditions can be effectively detected and intercepted in time to prevent the same flowing to the rear end assembly process; moreover, the resistance detection module is set to perform the resistance detection to the display region exceeding the threshold temperature in the AMOLED display panel to find out the positions appearing the short circuit and the micro short circuit in the AMOLED display panel for performing the accurate repair and raising the panel yield.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a structure block diagram of an AMOLED display panel detection device according to prior art;

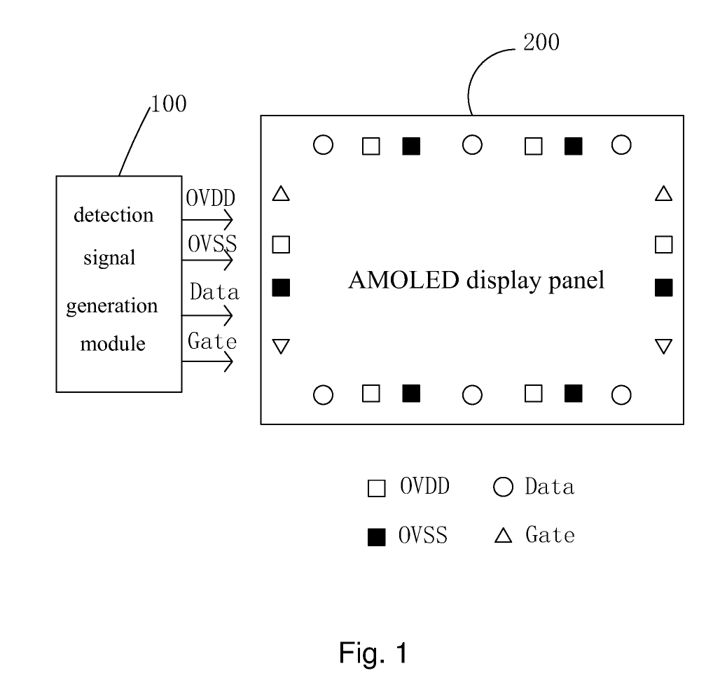

FIG. 2 is a flowchart of an AMOLED display panel detection method according to the present invention;

FIG. 3 is a structure block diagram of an AMOLED display panel detection device according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

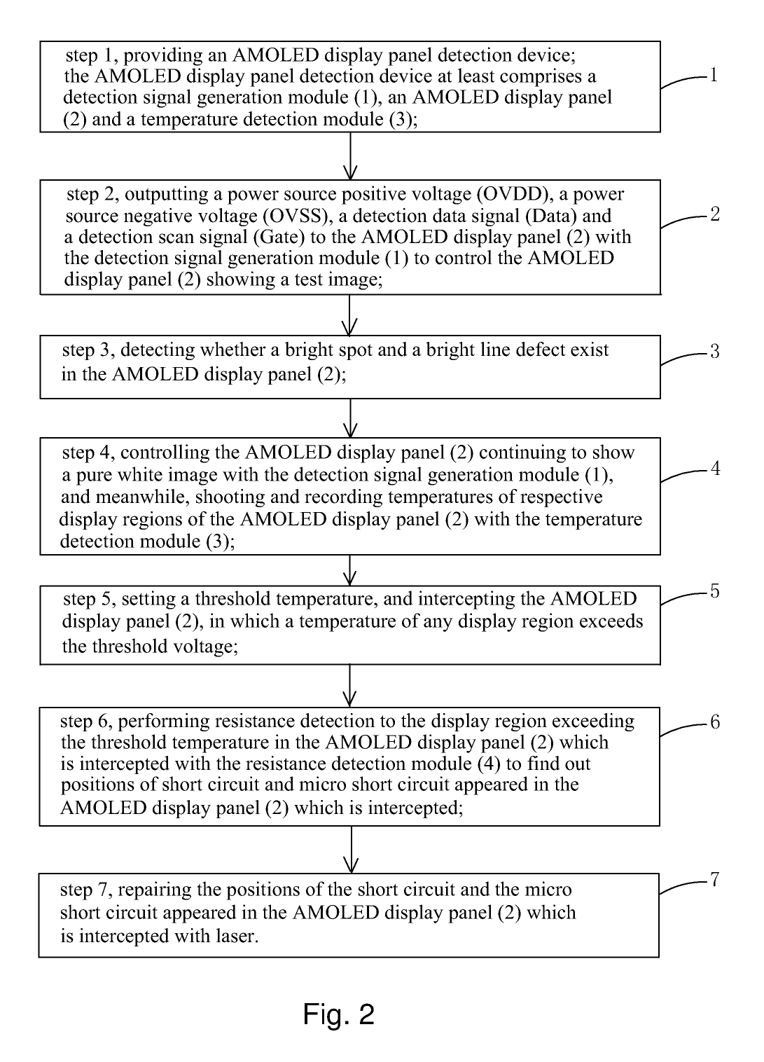

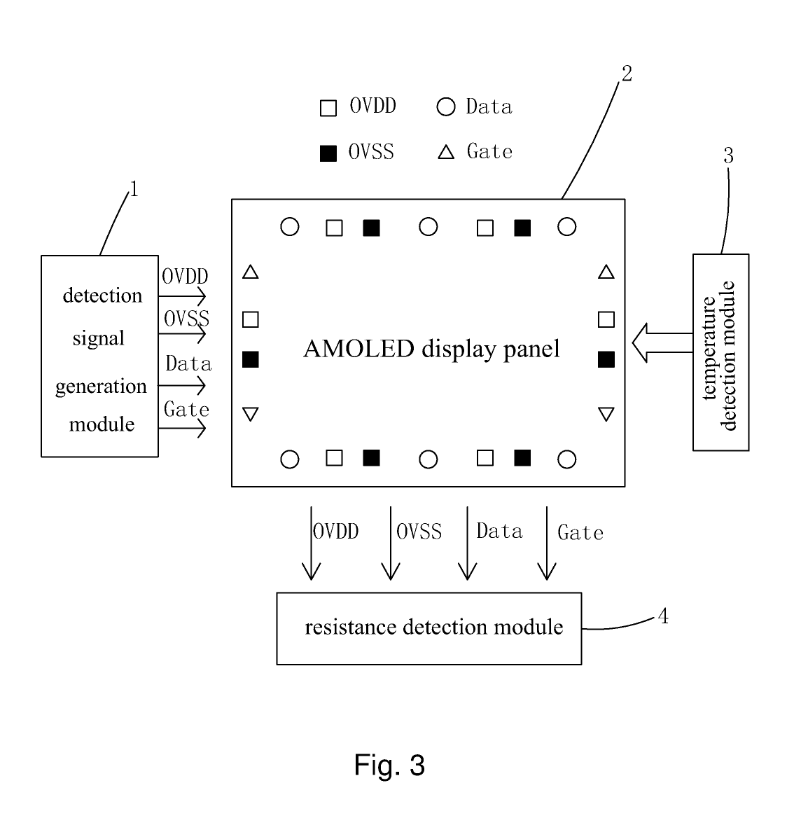

Please refer to FIG. 2 and FIG. 3 at the same time. The present invention first provides an AMOLED display panel detection method, comprising steps of:

step 1, providing an AMOLED display panel detection device.

As shown in FIG. 3, the AMOLED display panel detection device comprises a detection signal generation module 1, an AMOLED display panel 2 electrically coupled to the detection signal generation module 1, a temperature detection module 3 electrically to the AMOLED display panel 2 and a resistance detection module 4 electrically coupled to the AMOLED display panel 2.

step 2, outputting a power source positive voltage OVDD, a power source negative voltage OVSS, a detection data signal Data and a detection scan signal Gate to the AMOLED display panel 2 with the detection signal generation module 1 to control the AMOLED display panel 2 showing a test image.

Specifically, the AMOLED display panel 2 comprises test connection terminals corresponding to respective signals inside, which are respectively in charge of receiving the power source positive voltage OVDD, the power source negative voltage OVSS, the detection data signal Data and the detection scan signal Gate outputted by the detection signal generation module 1 to the AMOLED display panel 2 so that the AMOLED display panel 2 can show the test image. Furthermore, the test image is the test image of pure color image, such as pure black, pure red, pure green, pure blue or other common image used in the panel test technology in prior art.

step 3, detecting whether a bright spot and a bright line defect exist in the AMOLED display panel 2.

The function of the step 3 is employed to perform the regular detection to the test image of the AMOLED display panel 2. The technician observes the test image with eyes or with the image capture apparatus. Once the bright spot, the bright line are found, it indicates that the dot, line defects on the AMOLED display panel 2 exist.

step 4, after accomplishing the regular detection of the test image, controlling the AMOLED display panel 2 continuing to show a pure white image with the detection signal generation module 1, and meanwhile, shooting and recording temperatures of respective display regions of the AMOLED display panel 2 with the temperature detection module 3.

Specifically, the temperature detection module 3 is preferably to be a thermal imager; a duration that the AMOLED display panel 2 continues to show the pure white image is determined to be about 10 minutes for ensuring that the AMOLED display panel has enough warm up time.

In the executing procedure of the step 4, the AMOLED display panel 2 has short circuit and micro short circuit existing conditions in some display region, the temperature increase in the display region due to the increase of the current.

step 5, setting a threshold temperature, and intercepting the AMOLED display panel 2, in which a temperature of any display region exceeds the threshold voltage.

Specifically, the threshold temperature can be determined according to the factors of the type of the AMOLED display panel 2, the construction of the drive circuit, the materials, properties of the respective elements in the drive circuit. Once the temperature detection module 3 detects that the temperature of some display region in the AMOLED display panel 2 exceeds the threshold temperature, it indicates that the AMOLED display panel 2 has the short circuit and the micro short circuit existing conditions. Thus, the AMOLED display panel 2 having the short circuit and the micro short circuit existing conditions can be effectively detected and intercepted in time to prevent the same flowing to the rear end assembly process.

Furthermore, for promoting the production yield of the AMOLED display panels, the AMOLED display panel detection method of the present invention further comprises:

step 6, performing resistance detection to the display region exceeding the threshold temperature in the AMOLED display panel 2 which is intercepted with the resistance detection module 4 to find out positions of short circuit and micro short circuit appeared in the AMOLED display panel 2 which is intercepted.

Because in the step 6, the resistance detection is merely performed to the display region to the display region exceeding the threshold temperature in the AMOLED display panel 2 which is intercepted, namely, the resistance detection is performed to the display region, which is confirmed having the issues of the short circuit and the micro short circuit. The point is clear and the resistance detection time can be shortened. The positions appearing the short circuit and the micro short circuit in the AMOLED display panel 2 can be rapidly found out.

And step 7, repairing the positions of the short circuit and the micro short circuit appeared in the AMOLED display panel 2 which is intercepted with laser.

Specifically, in the step 7, the laser fuse is performed to the signal line appearing the short circuit and the micro short circuit, and then the laser welding is performed to the corresponding repair line to achieve the repair so that the AMOLED display panel returns to normal to promote the product yield.

On the basis of the same inventive idea, the present invention further provides an AMOLED display panel detection device. As shown in FIG. 3, the AMOLED display panel detection device of the present invention comprises a detection signal generation module 1, an AMOLED display panel 2 electrically coupled to the detection signal generation module 1, a temperature detection module 3 electrically to the AMOLED display panel 2 and a resistance detection module 4 electrically coupled to the AMOLED display panel 2. The temperature detection module 3 is preferably to be a thermal imager.

Specifically, the detection signal generation module 1 is employed for outputting a power source positive voltage OVDD, a power source negative voltage OVSS, a detection data signal Data and a detection scan signal Gate to the AMOLED display panel 2 to control the AMOLED display panel 2.

Specifically, the AMOLED display panel 2 is employed to show the test image, and comprises test connection terminals corresponding to respective signals inside, which are respectively in charge of receiving the power source positive voltage OVDD, the power source negative voltage OVSS, the detection data signal Data and the detection scan signal Gate outputted by the detection signal generation module 1 to the AMOLED display panel 2.

The temperature detection module 3 is employed for shooting and recording temperatures of respective display regions of the AMOLED display panel 2 as the AMOLED display panel 2 continues to show a pure white image. Once the temperature of some display region in the AMOLED display panel 2, which is detected with the temperature detection module 3, exceeds the threshold temperature, it indicates that the AMOLED display panel 2 has the short circuit and the micro short circuit existing conditions. The AMOLED display panel 2 needs to be intercepted to prevent the same flowing to the rear end assembly process.

The resistance detection module 4 is employed for performing resistance detection to the display region exceeding the threshold temperature in the AMOLED display panel 2 which is intercepted with the resistance detection module to find out positions of short circuit and micro short circuit appeared in the AMOLED display panel 2 which is intercepted for accurately repairing the positions of the short circuit and the micro short circuit.

Furthermore, the working procedure of the AMOLED display panel detection device according to the present invention:

First, the detection signal generation module 1 outputs the respective signals to the AMOLED display panel 2 to control the AMOLED display panel 2 to show the test image. The technician executes the regular detection to the test image, i.e. observes the test image with eyes or with the image capture apparatus. Once the bright spot, the bright line are found, it indicates that the dot, line defects on the AMOLED display panel 2 exist.

After accomplishing the regular detection of the test image, controlling the AMOLED display panel 2 continuing to show a pure white image in 10 minutes with the detection signal generation module 1, and meanwhile, shooting and recording temperatures of respective display regions of the AMOLED display panel 2 with the temperature detection module 3.

Then, the threshold temperature can be set according to the factors of the type of the AMOLED display panel 2, the construction of the drive circuit, the materials, properties of the respective elements in the drive circuit. Once the temperature of some display region in the AMOLED display panel 2, which is detected with the temperature detection module 3, exceeds the threshold temperature, it indicates that the AMOLED display panel 2 has the short circuit and the micro short circuit existing conditions. The AMOLED display panel 2 needs to be intercepted to prevent the same flowing to the rear end assembly process.

Finally, the resistance detection module 4 specifically performs the resistance detection to the display region exceeding the threshold temperature in the AMOLED display panel 2 which is intercepted to rapidly find out the positions appearing the short circuit and the micro short circuit in the AMOLED display panel 2 which is intercepted for providing the position reference for the following laser repair to promote the product yield.

In conclusion, in the AMOLED display panel detection method and the detection device of the present invention, the temperature detection module is set to shoot and record the temperatures of the respective display regions of the AMOLED display panel. As the temperature detection module detects that the temperature of some display region exceeds the threshold voltage, it indicates that the AMOLED display panel has the short circuit and the micro short circuit existing conditions. Thus, the AMOLED display panel having the short circuit and the micro short circuit existing conditions can be effectively detected and intercepted in time to prevent the same flowing to the rear end assembly process; moreover, the resistance detection module is set to perform the resistance detection to the display region exceeding the threshold temperature in the AMOLED display panel to find out the positions appearing the short circuit and the micro short circuit in the AMOLED display panel for performing the accurate repair and raising the panel yield.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An AMOLED display panel detection method, comprising steps of:
step 1, providing an AMOLED display panel detection device;
the AMOLED display panel detection device at least comprising a detection signal generation module, an AMOLED display panel electrically coupled to the detection signal generation module and a temperature detection module electrically to the AMOLED display panel;
step 2, outputting a power source positive voltage, a power source negative voltage, a detection data signal and a detection scan signal to the AMOLED display panel with the detection signal generation module to control the AMOLED display panel showing a test image;
step 3, detecting whether a bright spot and a bright line defect exist in the AMOLED display panel;
step 4, controlling the AMOLED display panel continuing to show a pure white image with the detection signal generation module, and meanwhile, shooting and recording temperatures of respective display regions of the AMOLED display panel with the temperature detection module;
step 5, setting a threshold temperature, and intercepting the AMOLED display panel, in which a temperature of any display region exceeds the threshold voltage.

2. The AMOLED display panel detection method according to claim 1, wherein the temperature detection module is a thermal imager.

3. The AMOLED display panel detection method according to claim 1, wherein in the step 4, a duration that the AMOLED display panel continues to show the pure white image is 10 minutes.

4. The AMOLED display panel detection method according to claim 1, wherein in the step 1, the AMOLED display panel detection device further comprises a resistance detection module which is electrically coupled to the AMOLED display panel.

5. The AMOLED display panel detection method according to claim 4, further comprising step 6, performing resistance detection to the display region exceeding the threshold temperature in the AMOLED display panel which is intercepted with the resistance detection module to find out positions of short circuit and micro short circuit appeared in the AMOLED display panel which is intercepted.

6. The AMOLED display panel detection method according to claim 5, further comprising step 7, repairing the positions of the short circuit and the micro short circuit appeared in the AMOLED display panel which is intercepted with laser.

7. An AMOLED display panel detection device, at least comprising a detection signal generation module, an AMOLED display panel electrically coupled to the detection signal generation module and a temperature detection module electrically to the AMOLED display panel.

8. The AMOLED display panel detection device according to claim 7, wherein the temperature detection module is a thermal imager.

9. The AMOLED display panel detection device according to claim 7, further comprising a resistance detection module which is electrically coupled to the AMOLED display panel.

10. An AMOLED display panel detection method, comprising steps of:
step 1, providing an AMOLED display panel detection device;
the AMOLED display panel detection device at least comprising a detection signal generation module, an AMOLED display panel electrically coupled to the detection signal generation module and a temperature detection module electrically to the AMOLED display panel;
step 2, outputting a power source positive voltage, a power source negative voltage, a detection data signal and a detection scan signal to the AMOLED display panel with the detection signal generation module to control the AMOLED display panel showing a test image;
step 3, detecting whether a bright spot and a bright line defect exist in the AMOLED display panel;
step 4, controlling the AMOLED display panel continuing to show a pure white image with the detection signal generation module, and meanwhile, shooting and recording temperatures of respective display regions of the AMOLED display panel with the temperature detection module;
step 5, setting a threshold temperature, and intercepting the AMOLED display panel, in which a temperature of any display region exceeds the threshold voltage;
wherein the temperature detection module is a thermal imager;
wherein in the step 4, a duration that the AMOLED display panel continues to show the pure white image is 10 minutes.

11. The AMOLED display panel detection method according to claim 10, wherein in the step 1, the AMOLED display panel detection device further comprises a resistance detection module which is electrically coupled to the AMOLED display panel.

12. The AMOLED display panel detection method according to claim 11, further comprising step 6, performing resistance detection to the display region exceeding the threshold temperature in the AMOLED display panel which is intercepted with the resistance detection module to find out positions of short circuit and micro short circuit appeared in the AMOLED display panel which is intercepted.

13. The AMOLED display panel detection method according to claim 12, further comprising step 7, repairing the positions of the short circuit and the micro short circuit appeared in the AMOLED display panel which is intercepted with laser.
